(19) United States
(12) Patent Application Publication
(10) Pub. No.: US 2026/0121636 A1
(43) Pub. Date: Apr. 30, 2026

(54) CONTROLLER, SYSTEM, AND METHOD FOR CONTROLLING OUTPUT DRIVER

(71) Applicant: InnoGrit Technologies Co., Ltd., Shanghai (CN)

(72) Inventors: Wei Jiang, Fremont, CA (US); Hongsen Yu, San Jose, CA (US); Yihan Wang, San Jose, CA (US); Gang Zhao, Chandler, AZ (US); Lin Chen, Cupertino, CA (US)

(21) Appl. No.: 18/932,998

(22) Filed: Oct. 31, 2024

(51) Int. Cl. H03K 17/687

(52) U.S. Cl. CPC H03K 17/6872

(57) ABSTRACT

A controller, for i=1, . . . , M, with M being a positive integer, is configured to cause a first non-infinite impedance between an output node (i) of an output driver (i) and a first voltage source (e.g., VDD) in a first time period during which the output node (i) is at a first logical value which is a digitized value of a second voltage source (e.g., ground). For example, the controller can maintain a digital 0 on the output node (i) without letting the analog voltage on the output (i) be pulled down to the analog ground, and/or can maintain a digital 1 on the output node (i) without letting the analog voltage on the output (i) be pulled up to the positive supply voltage.

### BACKGROUND

IO (input/output) drivers and transmitters may be used for high-speed data communication. IO drivers may incorporate equalization techniques such as pre-emphasis and de-emphasis. These techniques may help to alleviate signal degradation and to improve signal integrity at the receiver end.

De-emphasis is a technique of boosting high-frequency while attenuating low-frequency content of the signal to compensate for the signal loss caused by the transmission channel. For example, in a voltage-mode driver, the de-emphasis circuit may use a voltage divider network at the output stage of the driver to control the voltage swings for high-frequency and low-frequency components. The voltage divider network may have resistors and transistors that can be switched on or off by control signals. The level of de-emphasis can be adjusted by changing the number of switched elements of the resistors and capacitors.

For example, when an IO driver transmits a binary “01” or “10” in sequential order which is considered high-frequency data pattern, the driver de-emphasis circuit adjusts for a smaller driver impedance to generate a high-swing output. When the IO driver transmits continuous binary “11” or “00” which is considered low-frequency data pattern, the driver de-emphasis circuit adjusts for a low-swing output by using a higher driver impedance. In short, the traditional implementation of IO driver de-emphasis uses high driver impedance for low-frequency data patterns and low driver impedance for high-frequency data patterns. Static de-emphasis circuitry at the receiver end of the transmission channel and/or the transmitter end of the transmission channel has been implemented. Here, the word “static” in the context of the de-emphasis circuitry means that the de-emphasis circuitry does not vary de-emphasis based on the signal transmitted through the transmission channel.

### SUMMARY

Disclosed herein is a controller. For i=1, . . . , M, with M being a positive integer, the controller is configured to cause a first non-infinite impedance between an output node (i) of an output driver (i) and a same first voltage source in a first time period during which the output node (i) is at a first logical value which is a digitized value of a same second voltage source.

In an aspect, the controller is configured to cause a second non-infinite impedance between the output node (i) and the second voltage source in a second time period during which the output node (i) is at a second logical value which is a digitized value of the first voltage source.

In an aspect, the first voltage source is an operating voltage for input/output, and the second voltage source is ground.

In an aspect, M>1.

In an aspect, the first time period includes (A) a high-frequency time period for data on the output node (i), and (B) a low-frequency time period for data on the output node (i) immediately following the high-frequency time period, and the controller is configured to cause the first non-infinite impedance in the low-frequency time period.

In an aspect, the controller is configured to cause an infinite impedance between the output node (i) and the first voltage source in the entire high-frequency time period.

In an aspect, the controller is configured to cause a sixth non-infinite impedance between the output node (i) and the first voltage source in the high-frequency time period.

In an aspect, the first time period includes (A) a high-frequency time period for data on the output node (i), and (B) a low-frequency time period for data on the output node (i) immediately following the high-frequency time period. The controller is configured to: (A) cause a third impedance between the output node (i) and the second voltage source in the high-frequency time period, and (B) cause a fourth impedance between the output node (i) and the second voltage source in the low-frequency time period. The third impedance is lower than the fourth impedance.

In an aspect, the controller is configured to cause the fourth impedance over the entire low-frequency time period.

In an aspect, the low-frequency time period includes (A) a fifth time period, and (B) a sixth time period immediately following the fifth time period. The controller is configured to: (A) cause the fourth impedance in the fifth time period, and (B) cause a fifth impedance between the output node (i) and the second voltage source in the sixth time period. The fourth impedance is lower than the fifth impedance.

In an aspect, the first time period includes (A) a high-frequency time period for data on the output node (i), and (B) a low-frequency time period for data on the output node (i) immediately following the high-frequency time period, and the controller is configured to cause a third impedance between the output node (i) and the second voltage source in both the high-frequency time period and the low-frequency time period.

In an aspect, for each value of i, the output driver (i) comprises (A) Ki PMOS transistors electrically coupled to and between the output node (i) and the first voltage source, and (B) Ki NMOS transistors electrically coupled to and between the output node (i) and the second voltage source. The controller is configured to control ON/OFF states of the Ki PMOS transistors and thereby control an impedance between the output node (i) and the first voltage source. The controller is configured to control ON/OFF states of the Ki NMOS transistors and thereby control an impedance between the output node (i) and the second voltage source. The Ki, i=1, . . . , M are integers greater than 1.

In an aspect, Ki, i=1, . . . , M are the same.

In an aspect, for each value of i, and for j=1, . . . , Ki, the controller comprises a sub-controller (i, j) configured to generate 2 control signals respectively controlling ON/OFF states of (A) a PMOS transistor (i, j) of the Ki PMOS transistors of the output driver (i), and (B) an NMOS transistor (i, j) of the Ki NMOS transistors of the output driver (i).

In an aspect, the first time period includes (A) a high-frequency time period for data on the output node (i), and (B) a low-frequency time period for data on the output node (i) immediately following the high-frequency time period, and the controller is configured to generate a control signal (i) indicating the high-frequency time period or the low-frequency time period for data on the output node (i).

Disclosed herein is a system, comprising any controller above. The system is a solid-state drive (SSD), a flash drive, a mother board, a processor, a computer, a server, a gaming device, or a mobile device.

Disclosed herein is a method of using any controller above. The method includes, for i=1, . . . , M, causing with the controller the first non-infinite impedance between the output node (i) of the output driver (i) and the first voltage source in the first time period during which the output node (i) is at the first logical value which is a digitized value of the second voltage source.

In an aspect, the method further comprises causing with the controller the second non-infinite impedance between the output node (i) and the second voltage source in the second time period during which the output node (i) is at the second logical value which is a digitized value of the first voltage source.

In an aspect, the first time period includes (A) a high-frequency time period for data on the output node (i), and (B) a low-frequency time period for data on the output node (i) immediately following the high-frequency time period, and the controller causes the first non-infinite impedance in the low-frequency time period.

In an aspect, the controller causes an infinite impedance between the output node (i) and the first voltage source in the entire high-frequency time period.

In an aspect, the controller causes a sixth non-infinite impedance between the output node (i) and the first voltage source in the high-frequency time period.

In an aspect, the first time period includes (A) a high-frequency time period for data on the output node (i), and (B) a low-frequency time period for data on the output node (i) immediately following the high-frequency time period. The method further comprising: (A) causing with the controller a third impedance between the output node (i) and the second voltage source in the high-frequency time period, and (B) causing with the controller a fourth impedance between the output node (i) and the second voltage source in the low-frequency time period. The third impedance is lower than the fourth impedance.

The controller and method disclosed herein may allow dynamic de-emphasis, especially at the transmitter end of the transmission channel. Here, the word “dynamic” in the context of the de-emphasis circuitry means that the de-emphasis circuitry may vary de-emphasis based on the signal transmitted through the transmission channel. For example, the controller and method disclosed herein may vary the strength of or turn on or off de-emphasis based on the signal being transmitted.

### BRIEF DESCRIPTION OF FIGURES

FIG. 1 schematically shows an output driver system including a controller and multiple output drivers, according to an embodiment.

FIG. 2 schematically shows a mini-driver of the output driver system, according to an embodiment.

FIG. 3 schematically shows a sub-controller of the controller, according to an embodiment.

FIG. 4A-FIG. 4D show signal diagrams for generating control signals for the mini-driver, according to an embodiment.

FIG. 5 shows a flowchart generalizing the operation of the output driver system, according to an embodiment.

### DETAILED DESCRIPTION

### Output Driver System 100

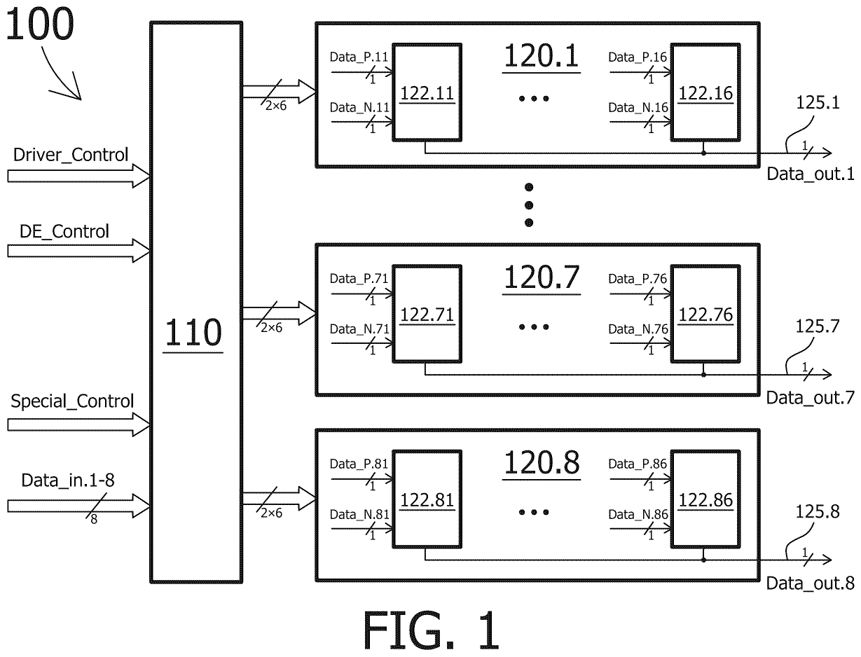

FIG. 1 schematically shows an output driver system 100, according to an embodiment. The output driver system 100 may include a controller 110 and M output drivers 120.1, 102.2, . . . , with M being a positive integer (e.g., M=8 as shown in FIG. 1). Each of the M output drivers may be individually referred to as “output driver 120.” The M output drivers may be collectively referred to as “output drivers 120.”

In an embodiment, the output driver system 100 may be part of a solid-state drive (SSD), a flash drive, a mother board, a processor, a computer, a server, a gaming device, or a mobile device (not shown).

### Controller 110

In an embodiment, with reference to FIG. 1, the controller 110 may receive as inputs including (A) data signals (e.g., Data_in.1, Data_in.2, . . . , and Data_in.8, or simply Data_in.1-Data_in.8) and (B) control signals (e.g., Driver_Control, DE_Control, and Special_Control) as shown in FIG. 1. The controller 110 may generate as outputs multiple control signals (e.g., 96 control signals, namely Data_P.11, Data_N.11, . . . , Data_P.86, and Data_N.86) for controlling the operations of the 8 output drivers 120.1-120.8 (as shown in FIG. 1).

### Output Driver 120

In an embodiment, with reference to FIG. 1, each output driver 120 of the output driver system 100 may include K mini-drivers (e.g., K=6 in FIG. 1). For example, the output driver 120.1 may include 6 mini-drivers 122.11-122.16. Each of the K mini-drivers may be individually referred to as “mini-driver 122.” The K mini-drivers may be collectively referred to as “mini-drivers 122.”

The numbers of mini-drivers 122 of the 8 output drivers 120 do not have to be the same. For example, the output driver 120.1 may have 6 mini-drivers 122, whereas the output driver 120.8 may have 10 mini-drivers 122.

### Mini-Driver 122

In an embodiment, with reference to FIG. 1, each mini-driver 122 of the output driver system 100 may receive as inputs 2 control signals Data_P and Data_N from the controller 110. For example, the mini-driver 122.11 may receive as inputs 2 control signals Data_P.11 and Data_N.11 from the controller 110.

In an embodiment, all the mini-drivers 122 of each output driver 120 may be electrically connected to the same output node of said each output driver 120. For example, all the 6 mini-drivers 122.11-122.16 of the output driver 120.1 may be electrically connected to the same output node 125.1, which carries a data output signal Data_out.1. The functions of the output driver system 100 include setting Data_out.i to Data_in.i in digital value, for i=1, . . . , 8.

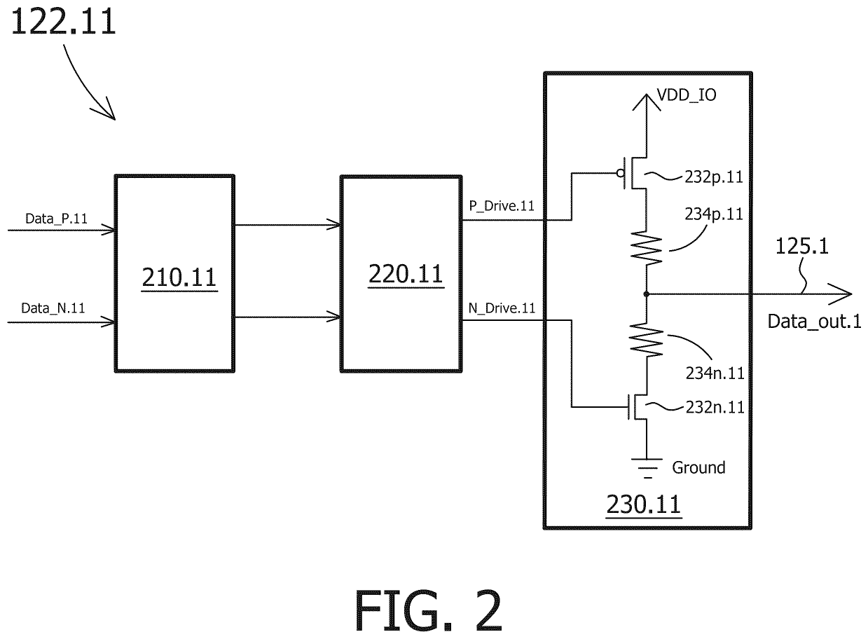

In an embodiment, with reference to FIG. 1 and FIG. 2, each of the 48 mini-drivers 122 of the output driver system 100 may include (A) a level shifter, (B) a pre-driver, and (C) a main driver. For example, with reference to FIG. 2, the mini-driver 122.11 of the output driver 120.1 may include (A) a level shifter 210.11, (B) a pre-driver 220.11, and (C) a main driver 230.11.

### Level Shifter 210 and Pre-Driver 220

In an embodiment, with reference to FIG. 1 and FIG. 2, the operation of the mini-driver 122.11 may be as follows. The 2 control signals Data_P.11 and Data_N.11 from the controller 110 may first enter the level shifter 210.11 to have their voltage levels transformed from core voltage domain to the input/output voltage domain (VDD_IO).

In an embodiment, the 2 control signals may further go through the pre-driver 220.11 which may include a group of logic gates (not shown) to further fine tune the strength and slew rate of the mini-driver 122.11. The 2 output signals P_Drive.11 and N_Drive.11 of the pre-driver 220.11 may be electrically connected to the main driver 230.11 for operation control.

### Main Driver 230

In an embodiment, with reference to FIG. 1 and FIG. 2, the main driver 230.11 may include a PMOS (p-channel metal oxide semiconductor) transistor 232p.11 electrically coupled between (A) an input/output operating voltage VDD_IO, and (B) the output node 125.1 of the output driver 120.1 through a resistor 234p.11 (as shown in FIG. 2). Another suitable device may be used in place of the PMOS transistor 232p.11.

In an embodiment, the main driver 230.11 may also include an NMOS (n-channel metal oxide semiconductor) transistor 232n.11 electrically coupled between (A) the ground Ground, and (B) the output node 125.1 of the output driver 120.1 through a resistor 234n.11 (as shown in FIG. 2). Another suitable device may be used in place of the NMOS transistor 232n.11.

In an embodiment, the 2 output signals P_Drive.11 and N_Drive.11 of the pre-driver 220.11 may switch on and off the PMOS transistor 232p.11 and the NMOS transistor 232n.11, respectively.

In an embodiment, the remaining 47 mini-drivers 122.12-122.86 of the output driver system 100 may be similar to the mini-driver 122.11 in terms of structure and function.

For the output driver 120.i (i=1, . . . , 8), the 6 PMOS transistors 232p.i1-232p.i6 are electrically coupled between VDD_IO and the output node 125.i in parallel, and the 6 NMOS transistors 232n.i1-232n.i6 are electrically coupled between Ground and the output node 125.i in parallel.

### Data_P AND Data_N For Controlling Mini-Driver 122

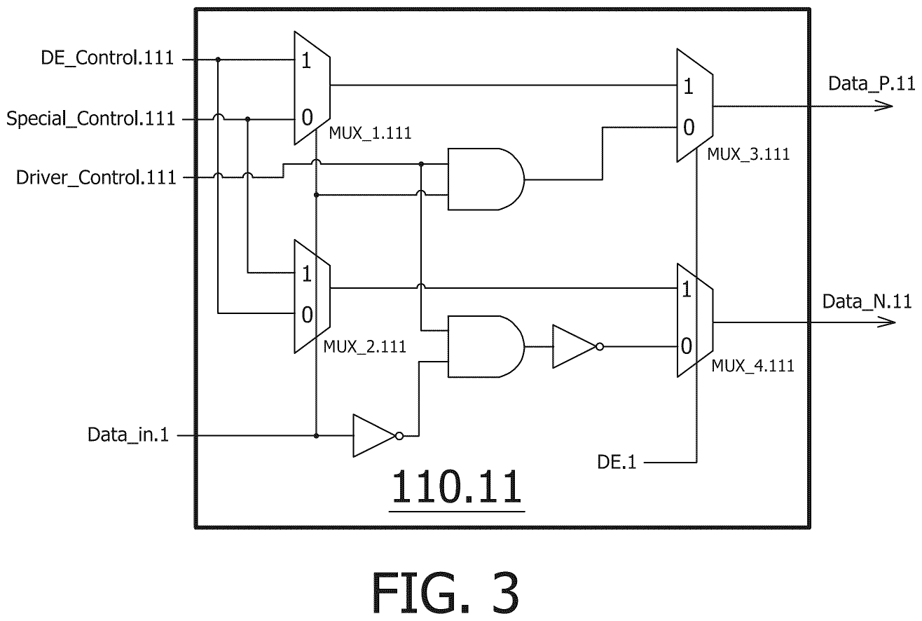

In an embodiment, with reference to FIG. 1-FIG. 3, the control signals Data_P.11 and Data_N.11 for controlling the mini-driver 122.11 may be generated by a sub-controller 110.11 (FIG. 3) of the controller 110 as follows.

Control signals Special_Control.111 and DE_Control.111 may first enter 2 multiplexers MUX_1.111 and MUX_2.111 of the sub-controller 110.11, with the multiplexer selection signal being Data_in.1.

When Data_in.1 is a logic “1” (or simply, Data_in.1=1), the Data_P.11 path may select DE_Control.111, and the Data_N.11 path may select Special_Control.111.

When Data_in.1 is a logic “0” (or simply, Data_in.1=0), the Data_P.11 path may select Special_Control.111, and the Data_N.11 path may select DE_Control.111.

Two additional multiplexers MUX_3.111 and MUX_4.111 of the sub-controller 110.11 may enable various pull-back levels when low-frequency data (i.e., continuous zeros and continuous ones) for Data_in.1 is transmitted. The 2 output signals of the multiplexers MUX_3.111 and MUX_4.111 may be Data_P.11 and Data_N.11 respectively.

A dynamic control signal DE.1 may be used as the multiplexer selection signal for the multiplexers MUX_3.111 and MUX_4.111.

When Data_in.1 is (A) continuous or adjacent zeros (e.g., 00 in two adjacent clock cycles) or (B) continuous or adjacent ones (e.g., 11 in two adjacent clock cycles), DE.1 may be set to 1, thereby selecting the data signal from the outputs of the multiplexers MUX_1.111 and MUX_2.111.

When Data_in.1 changes from 0 to 1 or from 1 to 0 between two adjacent clock cycles, DE.1 may be set to 0, thereby selecting the alternative path controlled by Driver_Control.111.

In an embodiment, DE.1 may be generated by an XNOR gate (not shown) that receives as inputs the current value of Data_in.1 and the previous value of Data_in.1. As a result, when the previous value and the current value of Data_in.1 are 00 or 11 (low-frequency change), DE.1 is 1; and when the previous value and the current value of Data_in.1 are 01 or 10 (high-frequency change), DE.1 is 0.

In an embodiment, the controller 110 may include 47 other sub-controllers (not shown) for controlling respectively the 47 mini-drivers 122.12-122.86. The 47 other sub-controllers may be similar to the sub-controller 110.11 in terms of structure and function.

In short, the controller 110 can control the ON/OFF states of each of the 48 PMOS transistors 232p and the 48 NMOS transistors 232n of the output driver system 100 individually.

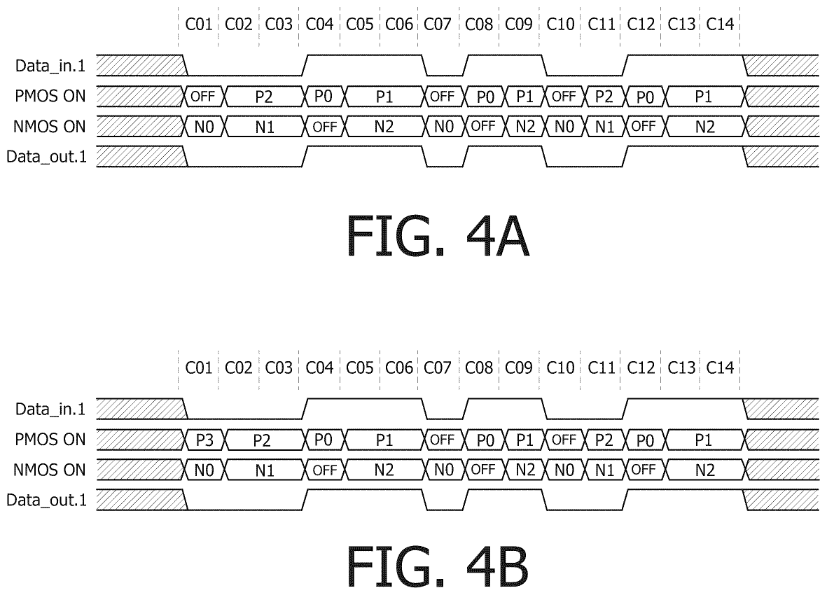

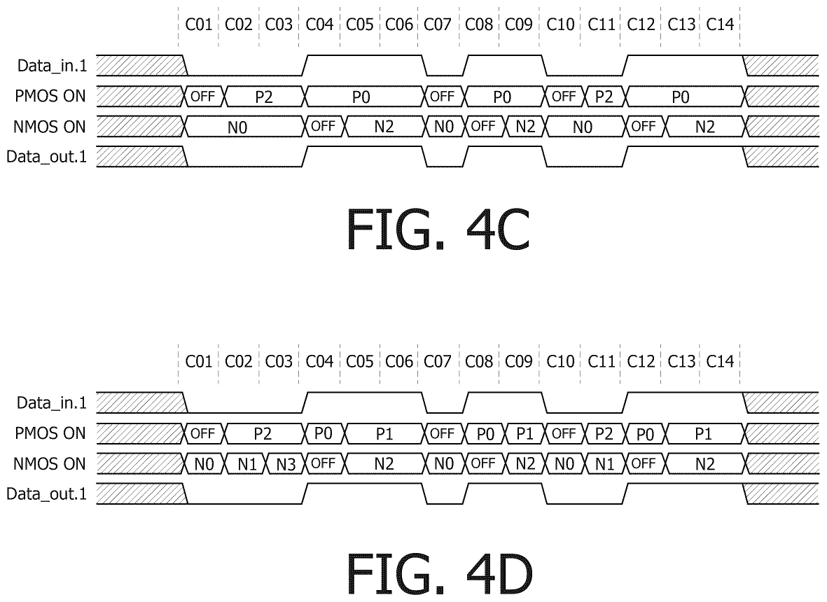

A high-frequency time period for a data signal (e.g., Data_in.1, Data_out.1, Data_in.8, Data_out.8, etc.) consists of a clock cycle for which the data signal changes from 0 to 1 or from 1 to 0 (in digital or logical value). For example, with reference to FIG. 4A, clock cycle C01 is a high-frequency time period for Data_in.1 (and also for Data_out.1 because Data_out.1=Data_in.1). Clock cycle C04 is another high-frequency time period for Data_in.1. Clock cycle C07 is yet another high-frequency time period for Data_in.1. Clock cycle C08 is yet another high-frequency time period for Data_in.1.

A low-frequency time period for a data signal (e.g., Data_in.1, Data_out.1, Data_in.8, Data_out.8, etc.) consists of one or more continuous clock cycles each of which is not a high-frequency time period. For example, with reference to FIG. 4A, clock cycles C02-C03 are a low-frequency time period for Data_in.1 (and also for Data_out.1 because Data_out.1=Data_in.1). Clock cycles C05-C06 are another low-frequency time period for Data_in.1. Clock cycle C09 is yet another low-frequency time period for Data_in.1.

### Operation of Output Driver System 100

In an embodiment, with reference to FIG. 1-FIG. 4A, the output driver 120.1 of the output driver system 100 may operate as follows.

Data_in.1 CHANGES FROM 1 TO 0

Assume for the clock cycle C01 that Data_in.1 changes from 1 to 0 (as shown in FIG. 4A). In response, in an embodiment, the controller 110 may cause NO of the K=6 NMOS transistors 232n.11-232n.16 of the output driver 120.1 to be ON (i.e., the remaining (K−N0) of the K=6 NMOS transistors are OFF). In other words, NMOS ON=N0 for clock cycle C01 (as shown in FIG. 4A). In an embodiment, NO may be a positive integer not exceeding K=6 (e.g., N0=5).

In addition, in an embodiment, the controller 110 may also cause all the K=6 PMOS transistors 232p.11-232p.16 of the output driver 120.1 to be OFF. In other words, the number of PMOS transistors 232p of the output driver 120.1 being ON is 0 (i.e., PMOS ON=0 or “OFF” for clock cycle C01 as shown in FIG. 4A).

For the high-frequency time period C01 for Data_in.1, the 6 NMOS transistors 232n.11-232n.16 of the output driver 120.1 not being all OFF (specifically, NO of them are ON) create a “non-infinite impedance” between the output node 125.1 and Ground, resulting in a primary force pulling down the output node 125.1 of the output driver 120.1 to Ground, while the 6 PMOS transistors 232p.11-232p.16 of the output driver 120.1 being all OFF create an “infinite impedance” between the output node 125.1 and VDD_IO, resulting in no pull-back force pulling up the output node 125.1 of the output driver 120.1 to VDD_IO.

As a result, the primary force without any pull-back force pulls the output node 125.1 of the output driver 120.1 down to Ground resulting in Data_out.1=Data_in.1=0 for clock cycle C01.

A primary force is a force that pulls the output node 125.1 toward a voltage potential (VDD_IO or Ground) so that Data_out.1=Data_in.1. In contrast, a pull-back force is a force that pulls the output node 125.1 in the opposite direction of the primary force.

Data_in.1 REMAINS AT 0

For the next clock cycles C02-C03, assume Data_in.1 remains at 0 (as shown in FIG. 4A). In response, in an embodiment, the controller 110 may cause N1 of the 6 NMOS transistors 232n.11-232n.16 of the output driver 120.1 to be ON. In other words, NMOS ON=N1 for clock cycles C02-C03 (as shown in FIG. 4A). In an embodiment, N1 may be a positive integer less than N0 (e.g., N0=5, and N1=3).

In addition, in an embodiment, the controller 110 may also cause P2 of the 6 PMOS transistors 232p.11-232p.16 of the output driver 120.1 to be ON. In other words, PMOS ON=P2 for clock cycles C02-C03 (as shown in FIG. 4A). In an embodiment, P2 may be a positive integer less than N1 (e.g., N1=3, and P2=2).

For the low-frequency time period C02-C03 for Data_in.1 (and also for Data_out.1), the 6 NMOS transistors 232n.11-232n.16 of the output driver 120.1 not being all OFF (specifically, N1 of them are ON) create a non-infinite impedance between the output node 125.1 and Ground, resulting in a primary force pulling down the output node 125.1 of the output driver 120.1 to Ground, while the 6 PMOS transistors 232p.11-232p.16 of the output driver 120.1 not being all OFF (specifically, P2 of them are ON) create a non-infinite impedance between the output node 125.1 and VDD_IO, resulting in a pull-back force pulling up the output node 125.1 of the output driver 120.1 to VDD_IO.

As a result, with the impedance between the output node 125.1 and Ground being less than the impedance between the output node 125.1 and VDD_IO (because N1=3>P2=2), the primary force overcomes the pull-back force, thereby causing Data_out.1=Data_in.1=0 for clock cycles C02-C03.

Data_in.1 CHANGES FROM 0 TO 1 AND REMAINS AT 1

In an embodiment, the operation of the output driver 120.1 when Data_in.1 changes from 0 to 1 (e.g., for the high-frequency time period C04) and then remains at 1 (e.g., for the low-frequency time period C05-C06) may be similar to the operation of the output driver 120.1 when Data_in.1 changes from 1 to 0 (for the high-frequency time period C01) and then remains at 0 (for the low-frequency time period C02-C03) described above.

In an embodiment, the operation of the remaining 7 output drivers 120.2-120.8 of the output driver system 100 may be similar to the operation of the output driver 120.1 described above.

### Operation Summary

In summary, with reference to FIG. 1-FIG. 4A, the controller 110 (A) causes a first non-infinite impedance (resulting from PMOS ON=P2) between the output node 125.1 of the output driver 120.1 and a first voltage source VDD_IO in a first time period C01-C03 during which the output node 125.1 is at a first logical value “0” (i.e., Data_out.1=0) which is a digitized value of a second voltage source Ground, and (B) causes a second non-infinite impedance (resulting from NMOS ON=N2) between the output node 125.1 of the output driver 120.1 and the second voltage source Ground in a second time period C04-C06 during which the output node 125.1 is at a second logical value “1” (i.e., Data_out.1=1) which is a digitized value of the first voltage source VDD_IO.

### Other Embodiments

### Pull-Back Force in Both High-Frequency Time Period and Low-Frequency Time Period

In the embodiments described above, with reference to FIG. 1-FIG. 4A, the controller 110 causes an infinite impedance between the output node 125.1 and VDD_IO (PMOS ON=OFF) in the high-frequency time period C01 for Data_out.1 (FIG. 4A). In an alternative embodiment, with reference to FIG. 4B, the controller 110 may cause a non-infinite impedance PMOS ON=P3 (with P3 being a positive integer less than NO) between the output node 125.1 and VDD_IO in the high-frequency time period C01 for Data_out.1.

### Same Primary Force in Both High-Frequency Time Period and Low-Frequency Time Period

In the embodiments described above, with reference to FIG. 4A, the controller 110 causes (A) NMOS ON=NO for the high-frequency time period C01 and (B) NMOS ON=N1 for the low-frequency time period C02-C03, where N1<NO. In an alternative embodiment, N1 may be the same as N0 (e.g., N0=N1=5). In other words, the controller 110 causes a same impedance between the output node 125.1 and Ground (e.g., NMOS ON=NO) in both the high-frequency time period C01 for Data_out.1 and the low-frequency time period C02-C03 for Data_out.1 (as shown in FIG. 4C).

### Two Different Primary Forces in Low-Frequency Time Period

In the embodiments described above, with reference to FIG. 4A-FIG. 4C, no more than one primary force is present in the low-frequency time period C02-C03 for Data_in.1. In an alternative embodiment, at least 2 different primary forces may be present in the low-frequency time period C02-C03 for Data_in.1. For example, with reference to FIG. 4D, 2 different primary forces (NMOS=N1 in C02, and NMOS=N3 in C03) may be present in the low-frequency time period C02-C03 for Data_in.1.

In an embodiment, N3 may be a positive integer less than N1. As a result, the impedance between the output node 125.1 and Ground in C02 (resulting from NMOS ON=N1) is lower than the impedance between the output node 125.1 and Ground in C03 (resulting from NMOS ON=N3).

### Flowchart Generalizing Operation of Output Driver System 100

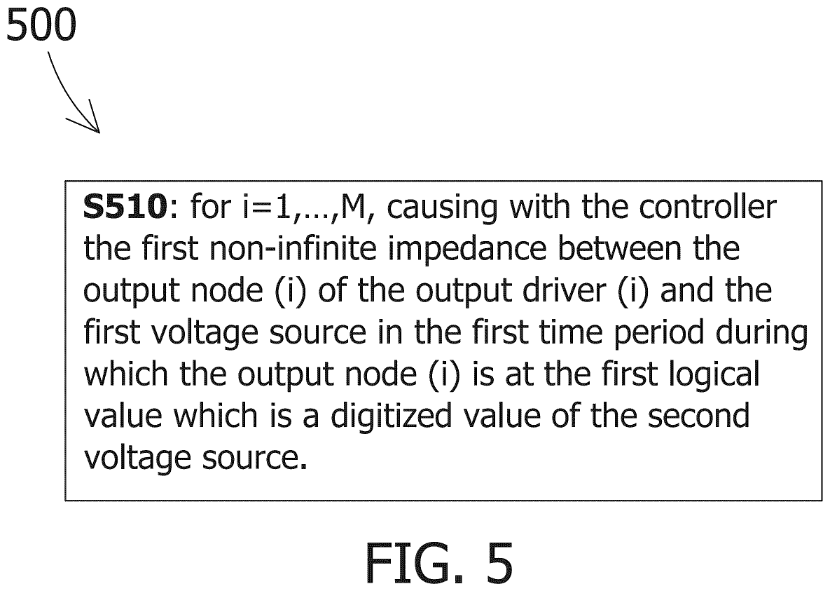

FIG. 5 shows a flowchart 500 generalizing the operation of the output driver system 100 of FIG. 1, according to an embodiment.

In step S510, the operation may include, for i=1, . . . , M, causing with the controller the first non-infinite impedance between the output node (i) of the output driver (i) and the first voltage source in the first time period during which the output node (i) is at the first logical value which is a digitized value of the second voltage source.

For example, in the embodiments described above, with reference to FIG. 1-FIG. 4A, the controller 110 causes the first non-infinite impedance (resulting from PMOS ON=P2) between the output node 125.1 of the output driver 120.1 and the first voltage source VDD_IO in the first time period C01-C03 during which the output node 125.1 is at the first logical value “0” (i.e., Data_out.1=0) which is a digitized value of the second voltage source Ground.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A controller, wherein for i=1, . . . , M, with M being a positive integer, the controller is configured to cause a first non-infinite impedance between an output node (i) of an output driver (i) and a same first voltage source in a first time period during which the output node (i) is at a first logical value which is a digitized value of a same second voltage source.

2. The controller of claim 1, wherein the controller is configured to cause a second non-infinite impedance between the output node (i) and the second voltage source in a second time period during which the output node (i) is at a second logical value which is a digitized value of the first voltage source.

3. The controller of claim 1,
wherein the first voltage source is an operating voltage for input/output, and
wherein the second voltage source is ground.

4. The controller of claim 1, wherein M>1.

5. The controller of claim 1,
wherein the first time period includes (A) a high-frequency time period for data on the output node (i), and (B) a low-frequency time period for data on the output node (i) immediately following the high-frequency time period, and
wherein the controller is configured to cause the first non-infinite impedance in the low-frequency time period.

6. The controller of claim 5, wherein the controller is configured to cause an infinite impedance between the output node (i) and the first voltage source in the entire high-frequency time period.

7. The controller of claim 5, wherein the controller is configured to cause a sixth non-infinite impedance between the output node (i) and the first voltage source in the high-frequency time period.

8. The controller of claim 1,
wherein the first time period includes (A) a high-frequency time period for data on the output node (i), and (B) a low-frequency time period for data on the output node (i) immediately following the high-frequency time period,
wherein the controller is configured to:
(A) cause a third impedance between the output node (i) and the second voltage source in the high-frequency time period, and
(B) cause a fourth impedance between the output node (i) and the second voltage source in the low-frequency time period, and
wherein the third impedance is lower than the fourth impedance.

9. The controller of claim 8, wherein the controller is configured to cause the fourth impedance over the entire low-frequency time period.

10. The controller of claim 8,
wherein the low-frequency time period includes (A) a fifth time period, and (B) a sixth time period immediately following the fifth time period,
wherein the controller is configured to:
(A) cause the fourth impedance in the fifth time period, and
(B) cause a fifth impedance between the output node (i) and the second voltage source in the sixth time period, and
wherein the fourth impedance is lower than the fifth impedance.

11. The controller of claim 1,
wherein the first time period includes (A) a high-frequency time period for data on the output node (i), and (B) a low-frequency time period for data on the output node (i) immediately following the high-frequency time period, and
wherein the controller is configured to cause a third impedance between the output node (i) and the second voltage source in both the high-frequency time period and the low-frequency time period.

12. The controller of claim 1,
wherein for each value of i, the output driver (i) comprises (A) Ki PMOS transistors electrically coupled to and between the output node (i) and the first voltage source, and (B) Ki NMOS transistors electrically coupled to and between the output node (i) and the second voltage source,
wherein the controller is configured to control ON/OFF states of the Ki PMOS transistors and thereby control an impedance between the output node (i) and the first voltage source,
wherein the controller is configured to control ON/OFF states of the Ki NMOS transistors and thereby control an impedance between the output node (i) and the second voltage source, and
wherein Ki, i=1, . . . , M are integers greater than 1.

13. The controller of claim 12, wherein Ki, i=1, . . . , M are the same.

14. The controller of claim 12, wherein for each value of i, and for j=1, . . . , Ki, the controller comprises a sub-controller (i, j) configured to generate 2 control signals respectively controlling ON/OFF states of (A) a PMOS transistor (i, j) of the Ki PMOS transistors of the output driver (i), and (B) an NMOS transistor (i, j) of the Ki NMOS transistors of the output driver (i).

15. The controller of claim 12,
wherein the first time period includes (A) a high-frequency time period for data on the output node (i), and (B) a low-frequency time period for data on the output node (i) immediately following the high-frequency time period, and
wherein the controller is configured to generate a control signal (i) indicating the high-frequency time period or the low-frequency time period for data on the output node (i).

16. A system, comprising the controller of claim 1, wherein the system is a solid-state drive (SSD), a flash drive, a mother board, a processor, a computer, a server, a gaming device, or a mobile device.

17. A method of using the controller of claim 1, comprising, for i=1, . . . , M, causing with the controller the first non-infinite impedance between the output node (i) of the output driver (i) and the first voltage source in the first time period during which the output node (i) is at the first logical value which is a digitized value of the second voltage source.

18. The method of claim 17, further comprising causing with the controller the second non-infinite impedance between the output node (i) and the second voltage source in the second time period during which the output node (i) is at the second logical value which is a digitized value of the first voltage source.

19. The method of claim 17,
wherein the first time period includes (A) a high-frequency time period for data on the output node (i), and (B) a low-frequency time period for data on the output node (i) immediately following the high-frequency time period, and
wherein the controller causes the first non-infinite impedance in the low-frequency time period.

20. The method of claim 19, wherein the controller causes an infinite impedance between the output node (i) and the first voltage source in the entire high-frequency time period.

21. The method of claim 19, wherein the controller causes a sixth non-infinite impedance between the output node (i) and the first voltage source in the high-frequency time period.

22. The method of claim 17,
wherein the first time period includes (A) a high-frequency time period for data on the output node (i), and (B) a low-frequency time period for data on the output node (i) immediately following the high-frequency time period,
wherein the method further comprising:
(A) causing with the controller a third impedance between the output node (i) and the second voltage source in the high-frequency time period, and
(B) causing with the controller a fourth impedance between the output node (i) and the second voltage source in the low-frequency time period, and
wherein the third impedance is lower than the fourth impedance.
